(19) United States
(12) Patent Application Publication
(10) Pub. No.: US 2011/0292598 A1
(43) Pub. Date: Dec. 1, 2011

(54) INTEGRATED EMBEDDED BATTERY

(75) Inventors: Keith J. HENDREN, Capitola, CA (US); Thomas W. WILSON, JR., Saratoga, CA (US); Robert L. COISH, Mountain View, CA (US); R. Sean MURPHY, Sunnyvale, CA (US)

(73) Assignee: APPLE INC., Cupertino, CA (US)

(21) Appl. No.: 12/869,542

(22) Filed: Aug. 26, 2010

Related U.S. Application Data
(60) Provisional application No. 61/349,616, filed on May 28, 2010.

(51) Int. Cl. G06F 1/16; H05K 13/00

(52) U.S. Cl. 361/679.55; 29/854

(57) ABSTRACT

A portable power source assembly including a plurality of battery cells that are directly attached to a housing used to enclose and support operational components of a portable computing device. A flexible interconnect component is used for electrically interconnecting the battery cells. Protective structures can be provided in discrete locations to protect the battery cells from compressive forces applied to the housing of the computing device. Removal handles or pull tabs may be provided on the battery cells so that individual battery cells may be easily removed for repair or replacement.

This application claims the benefit under 35 U.S.C. 119(e) of co-pending U.S. Provisional Patent Application No. 61/349,616, filed on May 28, 2010, which is hereby incorporated by reference herein in its entirety.

### BACKGROUND

1. Field of the Invention

The described embodiments relate generally to batteries for portable computing devices. More particularly, the present embodiments relate to battery packaging designs for portable computing devices.

2. Description of the Related Art

A design of a portable computing device can involve complex tradeoffs. A few factors that can be considered in the design process are cosmetic appeal, weight, manufacturability, durability, thermal compatibility and power consumption. A component that is selected on the basis of its positive contribution to one of these design factors can have an adverse impact on one of more of the other design factors.

A portable power source, typically a battery of some type, is an important component in the design of a portable computing device. The portable power source provides operating power for the portable computing device when it is not near a fixed power source, such as a wall outlet. Factors in selecting a portable power source can include energy density, form factor, and durability.

Energy density can refer to the amount of energy per given volume or per given mass that the portable power source is capable of delivering to the portable computing device. The form factor can refer to the shape of the package containing the portable power source. For instance, portable computing devices that are slim require an overall form factor for the portable power source that is also slim. The durability can relate to containment of any damaging elements associated with a battery cell. For example, portable power sources often include liquid or gel type electrolytes that need to be contained to prevent damage to other electronic components where the packaging needs to be durable enough to contain these damaging elements under normal operational conditions.

The energy density for a portable power device, such as a battery, can be affected by the type of battery cell that is employed and its associated packaging. The packaging design can affect the energy density in a number of ways. First, the energy density per mass will decrease as the mass of the packaging increases. The packaging decreases the energy density per mass because it adds mass to the system without providing additional energy. The mass of the packaging design can be constrained by durability considerations.

Second, the energy density per volume is affected by packing efficiency where the packing efficiency can be constrained by a desired form factor for the packaging design. An inefficiently packaged battery cell can have a lower energy density per volume than an efficiently packaged battery cell. As the energy density per volume decreases, the volume taken up by the portable power device increases, which can be undesirable for utilization with a portable computing device.

In a portable computing device, it is generally desirable to minimize the weight and volume of each component while still maintaining desired functionality and performance levels. Therefore, it would be beneficial to provide a housing assembly for a battery useable in at least a portable computing device that is durable, lightweight and efficiently packaged. It would also be beneficial to provide methods for assembling the battery that meet the above conditions and perform satisfactorily during operational cycling of the device.

### SUMMARY

This paper describes various embodiments that relate to systems, methods, and apparatus for enclosures for use in portable computing applications.

According to an embodiment, a power supply assembly for a computing device is described. The power supply assembly includes a plurality of battery cells. Each battery cell is directly attached to a housing for enclosing the operational components of the portable computing device. Each of the battery cells includes an electrode assembly including an anode, a cathode, and an electrolyte. The power supply assembly also includes a protective structure adjacent to a battery cell for protecting the battery cell from a compressive force applied to the housing of the portable computing device. The protective structure, which can be a frame or a discretely positioned structural rib, can be attached to or with the housing and has a height greater than that of each of the battery cells.

According to another embodiment, a power source for a portable computing device is described. The power source includes a plurality of battery cells directly adhered to a housing of the portable computing device, an interconnect component electrically interconnecting the plurality of battery cells, and a protective structure in close proximity to the battery cells. The battery cells can have shapes that can conform to a shape of a corresponding portion of the housing. The interconnect component is positioned such that portions of the interconnect component are positioned between a battery cell and the housing. The protective structure is configured to protect a battery cell from damage due to a compressive force on the housing. According to an embodiment, the protective structure is formed integrally with the housing.

A method of assembling a power supply assembly in a computing device is disclosed. An interconnect component is positioned over a base portion of a housing of the computing device. A plurality of battery cells is then positioned over the interconnect component and the base portion such that portions of the interconnect component are underneath the battery cells. The battery cells are then adhered directly to the base portion in portions where the interconnect component is not underneath the battery cells. The battery cells can conform to the shape of the housing. The battery cells can also be positioned in close proximity to a protective structure, such as a frame around the perimeter of a battery cell or ribs positioned discretely to protect the battery cell from compressive forces applied to the housing of the computing device.

Other aspects and advantages of the invention will become apparent from the following detailed description taken in conjunction with the accompanying drawings which illustrate, by way of example, the principles of the invention.

### BRIEF DESCRIPTION OF THE DRAWINGS

The invention will be readily understood by the following detailed description in conjunction with the accompanying drawings, wherein like reference numerals designate like structural elements, and in which:

FIG. 1 shows a perspective view of components of a portable power source prior to assembly.

FIG. 2 shows a close up view of electrical tabs and flex.

FIG. 3 shows a top view of the flex positioned on the base portion of the housing.

FIG. 4 shows a side cross-sectional view of a battery cell and its connection at the terrace region to a flex and external circuitry.

FIG. 5 shows a detailed cross section of terrace interconnects.

FIGS. 6-8 show snap and lollipop type connections for connecting a battery cell to a flex.

FIG. 9 shows a battery cell positioned adjacent discretely positioned structural ribs.

FIG. 10 shows a protective frame that can be positioned around the perimeter of a battery cell.

FIG. 11 shows a perspective view of a removal handle attached to a battery cell.

FIG. 12 is a flow chart of a method of attaching and connecting an embodiment of a portable power supply assembly in an electronic device.

### DETAILED DESCRIPTION OF SELECTED EMBODIMENTS

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The following description relates to power supply assemblies formed of a plurality of individual battery cells. Each battery cell is adhesively attached to a portion of an inner wall of a housing that encloses operational components of a portable computing device. In the described embodiments, the housing used to enclose and support the operational components can be formed of a front portion and a rear portion. The front portion is suitable for providing support for a display element, such as a display screen, and input devices, such as a keyboard and/or track pad. The rear or base portion of the housing can be used as the structure onto which the plurality of battery cells is attached. During assembly, the rear portion and the front portions can be brought together and physically secured to each other using any suitable attachment mechanism, such as screws. The individual battery cells can be each directly attached to the rear portion of the housing an adhesive, such as, for example, VHB™ type adhesive. A VHB™ double-sided bonding tape is commercially available from 3M Company of St. Paul, Minn.

The direct attachment of each battery cell to the housing obviates the need for a separate battery support/protection structure, such as a battery case that is typically used in a conventional battery pack. Such battery cases are typically plastic enclosures around the battery cells. The plastic enclosures are separate from the computer or device housing. By eliminating the battery case, the overall weight and z stack height of the power supply assembly can be reduced over that required for a conventional battery pack.

In the described embodiments, the individual battery cells can be electrically connected to each other by way of a flexible connector, or flex. Each flexible connector can be electrically connected to the battery cells at connection tabs located on a battery cell compression band usually formed of an insulating plastic material. In order to preserve space, the connections used to connect the tabs on each battery cell to the flexible connector are placed with a region referred to as a battery terrace, or more simply, terrace. The terrace region is located on an end of the battery cell. Furthermore, battery cell related circuitry, such as a battery management unit (BMU), can be discretely coupled to or integrated with the flexible connector at the battery terrace region. In some embodiments, the BMU can be used for all of the battery cells in the device. The flexible connector can be soldered onto the BMU.

In those cases where the battery cells are formed of a compliant material, such as a jelly roll type battery cell, protection from compression caused by, for example, a drop event, can be provided by a series of structural ribs or a protective frame that can be attached at the rear portion of the housing between adjacent battery cells. The ribs or frame can be shaped and sized to contact both the rear portion and the front portion of the housing when assembled. In this way, any forces applied at either the front or rear portions are transferred around the individual battery cells by the structural ribs. The protective frame could also be provided with electrical circuitry and cell mounting tabs and serve as an electrical connector.

One advantage of the power supply assembly is that since the battery cells are directly attached to the rear portion of the housing, there is no need for a separate battery enclosure or pre-assembly as would be required with the use of a battery pack. By obviating the need for pre-assembly, there is no need for a separate battery pack vendor because an inventory of battery cells is all that is required to assemble the power supply assembly. Moreover, any repair and replace operations can be easily carried out using pull tabs or removal handles that can be placed on a portion of the battery cells. Such tabs would facilitate removal of a battery cell that needs to be repaired or replaced. For example, a pull tab can be placed on a side of the battery cell opposite the compression band; the pull tab can then be used to easily remove the defective battery cell by simply pulling on the tab.

The power supply assembly can be electrically connected to external circuitry, such as a main logic board (MLB), by way of any number and type of suitable electrical connectors. For example, a male portion of a blade type connector can be electrically connected to the flexible connector during assembly; the male portion of the blade type connector can mate with a corresponding female connector at the MLB. Since the assembly operation is typically a blind “bottom-up” type blind assembly, the blade assembly makes it easier to align and therefore provides an easy assembly operation. Other connectors that can be used include a spring type connector along the lines of a spring finger connector attached to the MLB in one embodiment arranged to make electrical contact with contact pads as part of the portable battery assembly. In such an arrangement, contacts can be provided on the flexible connector or on the spring finger. Of course, the arrangement can be such that the spring finger connector is part of the portable power supply.

The power supply assembly can be suitable for a portable computing device, such as, but not limited to a laptop computer, netbook computer, tablet computer, smart phone, a portable media player, etc. In particular, the housing assembly comprises a battery cell with a support structure comprising at least two electrically conductive tabs.

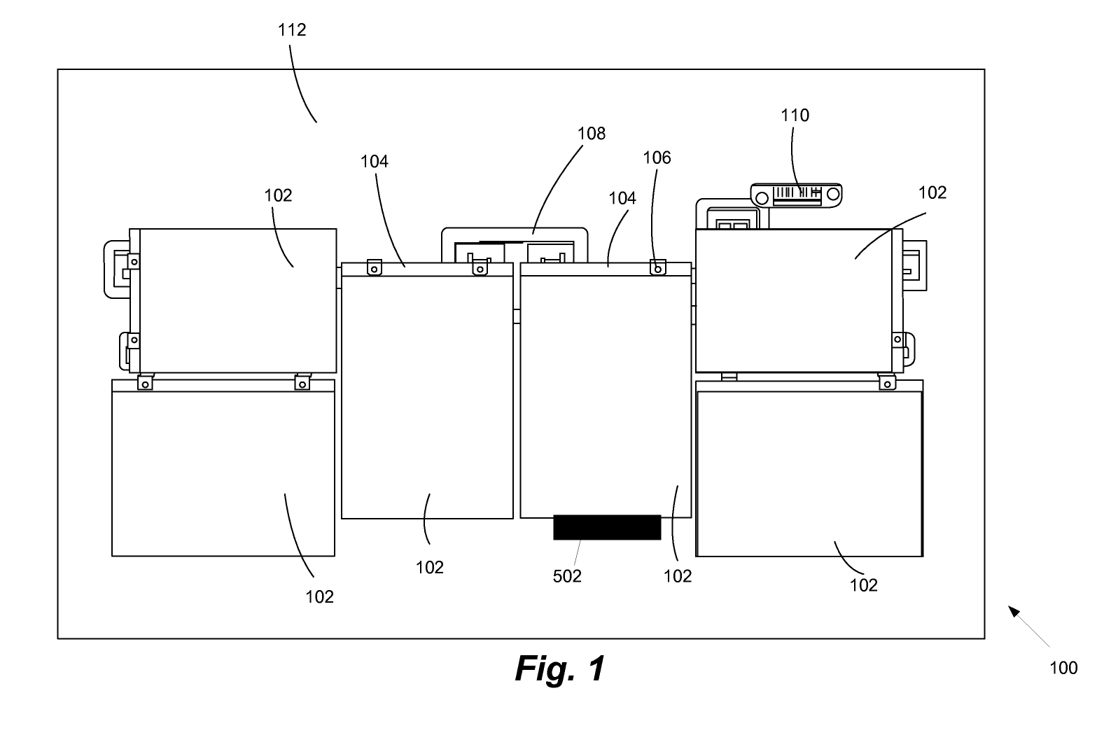

FIG. 1 shows a perspective view of components of an embodiment of a power supply assembly 100. The power supply assembly 100 can include a plurality of battery cells 102 each formed by, for example, jelly roll assembly. As will be discussed in more detail below, the battery cells 102 can be of different types, sizes, and numbers, and can be distributed in different configurations.

Each of the plurality of battery cells 102 can include compression band 104 that is used to provide support for the battery cell 102 to which it is attached. As shown in FIG. 1, the compression band 104 can be located at one end of the battery cell 102. The compression band 104 can be formed of plastic and include metal connection, or electrode, tabs 106 used to electrically connect each battery cell 102 to the flexible connector, or flex, 108 that can in, turn, be connected to power supply connector 110. The power supply connector 110 can be used to electrically connect power supply assembly 100 to external circuitry, such as a main logic board (MLB).

In the described embodiment, each battery cell 102 is attached directly to a base portion 112 of a housing used to enclose and support operational components of a computing device, such as a portable computer. In the described embodiments, each battery cell 102 can comprise a sheet with a number of layers, such as a layer of cathode material, a layer of anode material and a separator material between the anode and cathode layer. The sheet can be rolled or folded up to form the battery cell 102. In one embodiment, the cathode material can include lithium. The lithium anode material along with a suitable cathode material, such as porous carbon, can be used to form a lithium ion type battery. In other embodiments, the battery cell 102 can be a stacked cell.

In a particular embodiment, a liquid or gel electrolyte can be used with the battery cell 102. A lithium ion battery is an example of a battery system using a liquid or gel electrolyte. In another embodiment, a dry electrolyte, such as a polymer electrolyte can be used with the battery cell 102. A dry lithium polymer battery is one example of a battery system employing a dry electrolyte. In particular embodiments, a gel or liquid electrolyte can be used in combination with a dry electrolyte, such as the polymer electrolyte. For instance, a lithium ion polymer battery uses a polymer electrolyte in combination with a liquid or gel electrolyte. The liquid or gel electrolyte can be added to improve the conductivity of the battery system at lower temperatures, such as at room temperature conditions or colder.

As the battery cells 102 are attached directly to the base portion 112 of the housing, the cells 102 can be configured to conform to the shape of the inner wall of the base portion 112 to which the battery cells 102 are directly attached. By conforming the shape of the battery cells 102 to the shape of the base portion 112 of the housing, more efficient packing can be achieved and the device can consequently be made smaller. For example, the inner wall of the base portion 112 may have a curved surface. If the battery cell 102 has a corresponding curved surface, the volume within the housing that is taken up by the battery cell 102 can be minimized and the available volume for other components can therefore be maximized. In other embodiments, the inner wall of the base portion 112 may have a flat surface and the battery cell 102 would have a corresponding flat surface.

The battery cell 102 can comprise electrode tabs 106 on the compression band 104, as shown in FIG. 1. The electrode tabs 106 can include a positive and a negative tab. The electrode tabs 106 can be surrounded by a compression band 104 formed of insulating material, such as plastic, to prevent shorts from occurring across the two electrode tabs 106.

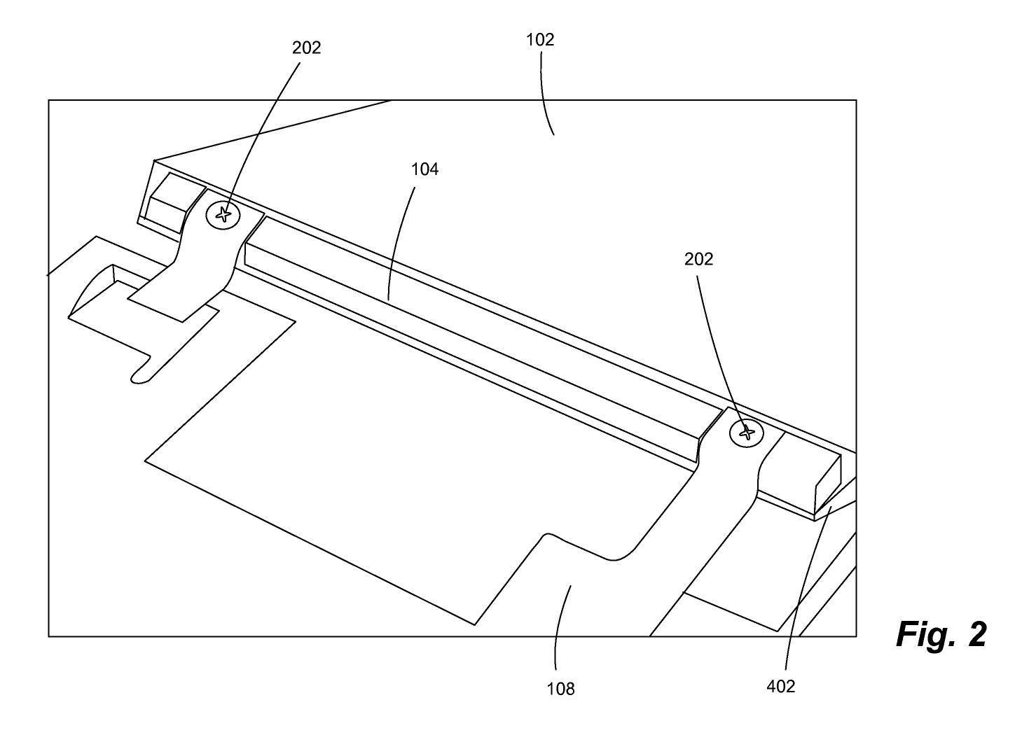

The electrode tabs 106 can be electrically connected to the flex 108, as shown in FIG. 2, using metal fasteners, such as screws 202. It will be understood that other fastening methods, such as spot welding or snaps, can be used instead of screws. The electrode tabs 106 can electrically connect the battery cell 102 to safety circuitry connected to the flex 108 that can be configured to cut off current from the battery cell 102. As an example, the safety circuit can be configured to shut down the battery when it is charged above a certain voltage level and discharged below a certain voltage level. In a particular embodiment, the safety circuitry can include an element, such as a thermal interrupt that opens a circuit in response to an over current and/or overcharging conditions. In particular embodiments, the safety circuitry can include one or more sensors for detecting conditions of the battery, such as current and voltage levels. This information can be used to determine a charge remaining in the battery cell 102. In addition, other safety features that can be associated with the portable power source include, but are not limited to, circuitry or a device that responds 1) to over-temperature conditions, such as a shut down separator and 2) internal pressure conditions, such as a tear-away tab or a vent.

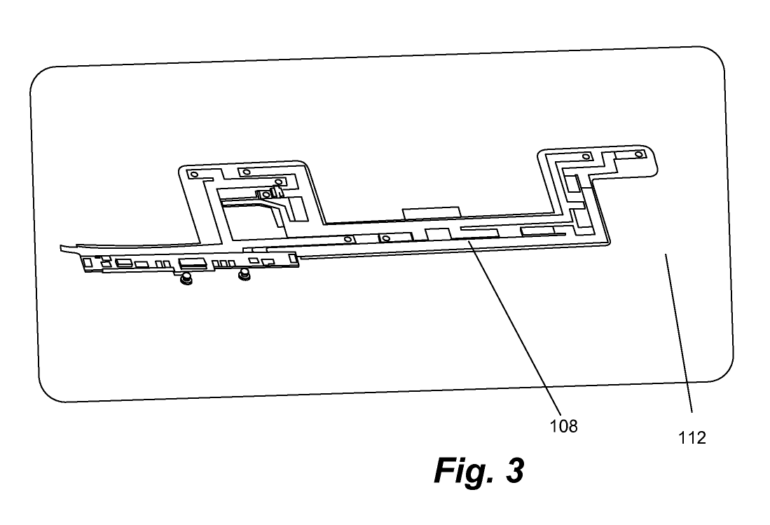

As discussed above, battery interconnect is achieved through the flexible interconnect, or flex 108. FIG. 3 is a top plan view of a flex 108 positioned on a base portion 112 of the housing before the battery cells 102 are positioned over and adhered to the base portion 112. The flex 108 can be formed of a thin layer of flexible material, which can conform to the shape of the inner wall of the base portion 112 of the housing.

Portions of the flex 108 can be positioned underneath the battery cells 102. That is, the battery cells 102 are positioned over portions of the flex 108 when the power supply assembly 100 is assembled on the base portion 112 of the housing. By positioning portions of the flex 108 underneath the battery cells 102, the available volume in the housing for other components is maximized, especially in the z-direction. Furthermore, as the flex 108 is formed of a flexible material, it can easily conform to the shape of the base portion 112 of the housing as well as the battery cells, thereby maximizing the available volume of the housing in the z-direction. The battery cells 102 can also provide protection to the flex 108 positioned underneath the battery cells 102. Furthermore, it simplifies assembly, thereby providing cost savings to the manufacturer.

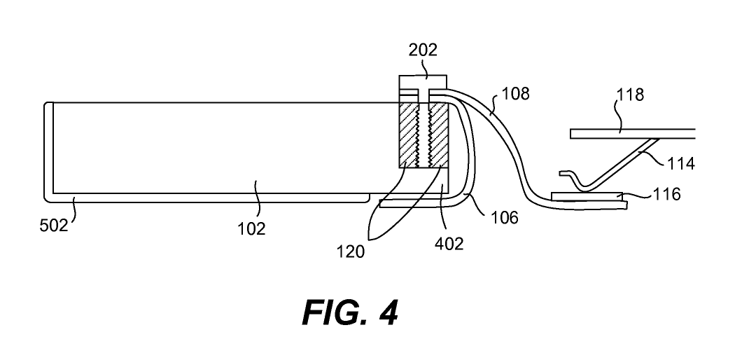

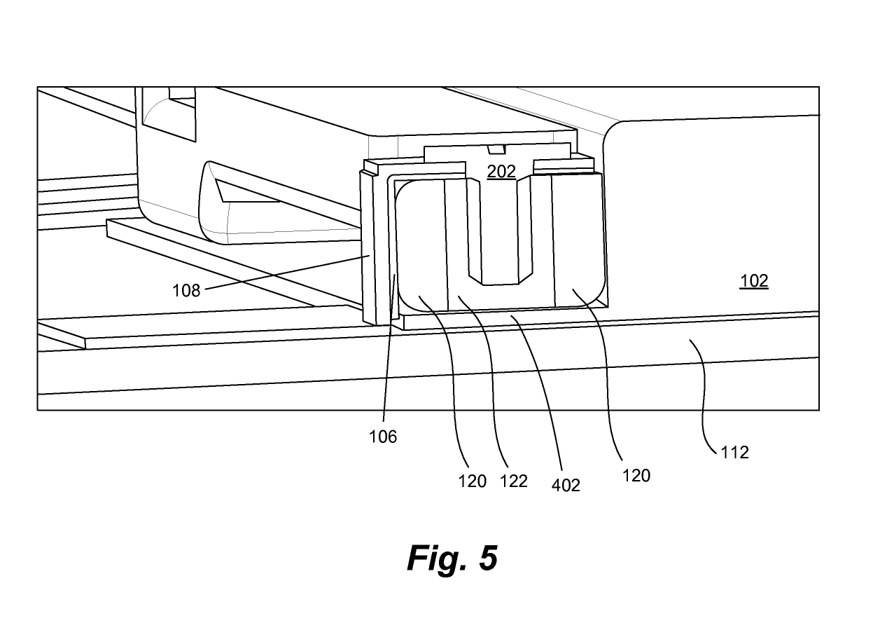

FIG. 4 is a side cross-sectional view of a battery cell 102 with a flex 108 connection at the terrace 402. FIG. 5 shows a detailed cross section of a terrace interconnection in accordance with the described embodiments. Use of the terrace region 402 for the interconnects allows for a reduced footprint, thereby minimizing the size of the device.

Typically, in a battery, a temperature cut off (TCO) mechanism or thermal fuse is incorporated to prevent the battery from overheating. Such a TCO is typically located on the terrace, but in some embodiments, the TCO can be located on the flex 108 by integrating a thermal fuse on the flex 108 circuit.

In some embodiments, as shown in FIG. 4, a spring finger contact may be provided instead of a blade type connector 110 to electrically connect the power supply assembly 100 to external circuitry, such as the MLB. As shown in FIG. 4, a spring finger connector 114 can connect the MLB 118 with a contact pad 116 on the flex 108. It will be understood that a contact can alternatively be provided on the spring finger.

The flex 108 can include tab portions that can bend up and over to connect to the electrode tabs 106, as shown in FIGS. 4 and 5. As shown in FIGS. 4 and 5, the tab portions of the flex 108 can be provided with a screw hole and held in place by screws 202. FIGS. 4 and 5 show a screw 202 threaded into an insert 120, which can be a threaded plastic insert or boss. The skilled artisan will appreciate that the plastic material can be insulating. According to an embodiment, the plastic boss can be molded onto the base portion 112 and a PEM insert 122 can be installed for thread durability, as shown in FIG. 5. The screw 202 is used to compress the tab portion of the flex 108 and the electrode tab 106 to maintain contact. If a battery cell 102 needs to be repaired or replaced, the screws 202 can simply be loosened and removed to disconnect the battery cell 102.

In some embodiments, the electrode tab 106 can be positioned over the tab portion of the flex 108. In other embodiments, the tab portion of the flex 108 can be positioned over the electrode tab 106, as shown in FIG. 4.

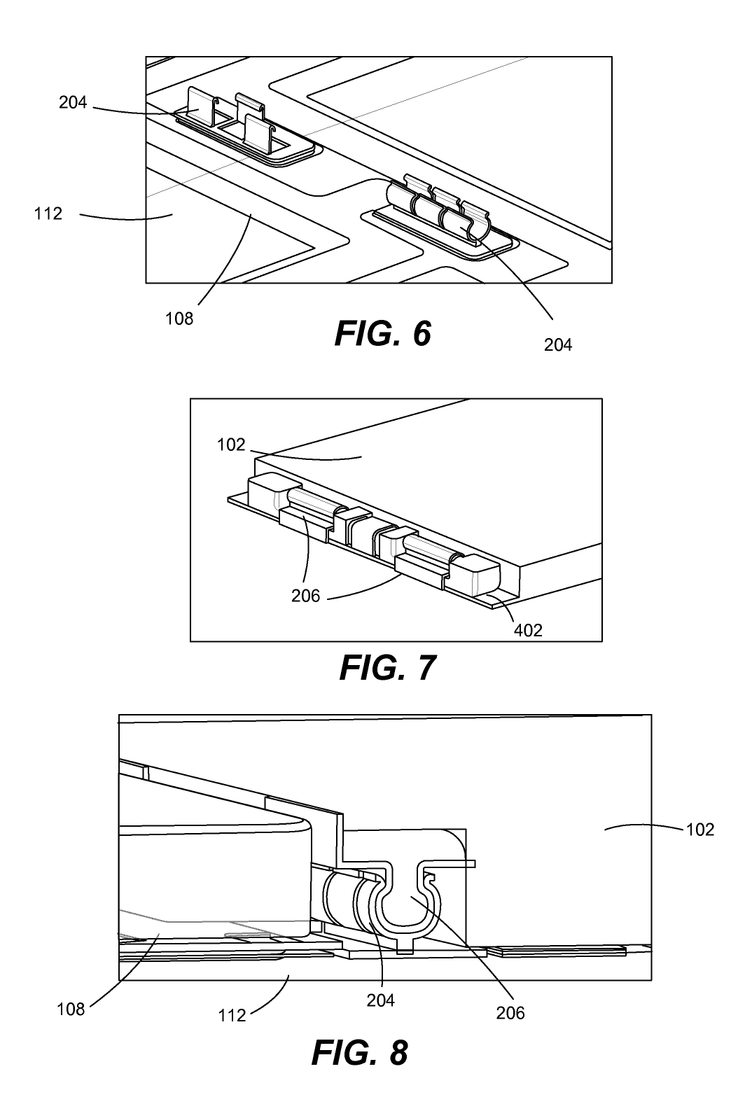

It will be understood that in other embodiments, alternative connection methods, such as spot welding or snaps can be used instead of screws. For example, FIGS. 6-8 illustrate a snap-lollipop type interconnect for electrically connecting the flex 108 and the battery cell 102. As shown in FIG. 6, the snap and lollipop components 204 can be provided on the flex 108. FIG. 7 shows the underside of a battery cell with corresponding snap and lollipop components 206 on the terrace 402 that are configured to snap in to the components 204 on the flex 108. As can be appreciated, the snap and lollipop type interconnect allows for easy connection and removal of a battery cell. FIG. 8 shows the connection of the battery cell 102 with the flex 108, with the component 206 engaged in component 204. Alternatively, components 204 can be attached to or integral with the base portion 112 of the housing.

As mentioned above, the battery cells 102, such as a jelly-roll type battery, may be formed of compliant and compressible materials. A protective structure, such as a rib or frame, can be positioned in close proximity to the battery cells 102 to protect the battery cells 102 from potentially damaging compressive forces. The protective structure can have a height higher than that of the battery cells 102 and contact both the base portion 112 and the top portion of the housing to withstand any compressive force coming from the base portion 112 and/or the top portion of the housing.

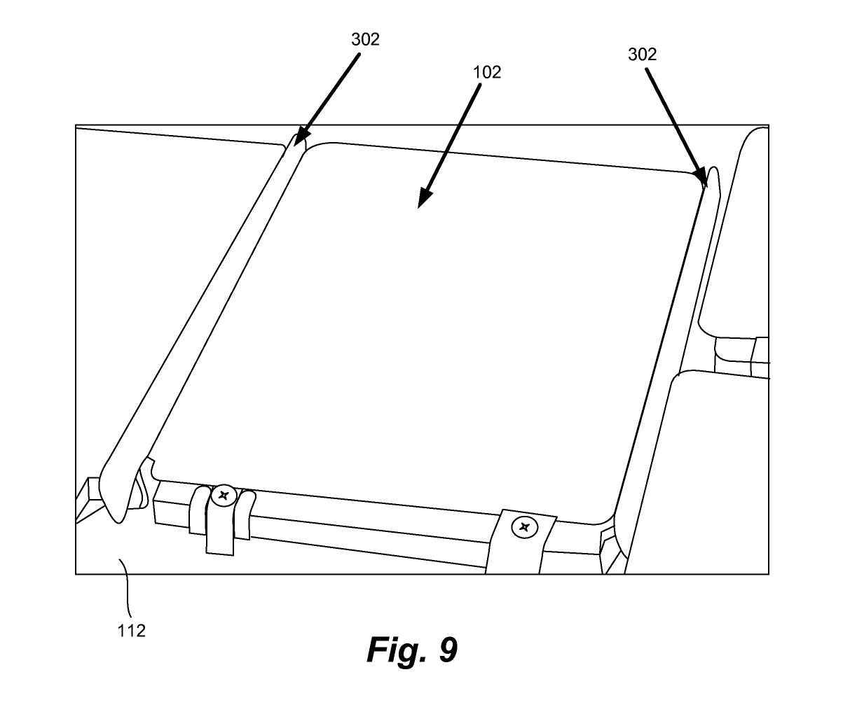

FIG. 9 shows protective ribs 302 that can be used to provide structural support and protection against compression of the battery cells 102 that can be caused by, for example, a drop event. As shown in FIG. 9, the ribs 302 extend at a substantially right angle up from the inner face of the base portion 112 and can contact the top portion of the housing. The ribs 302 can be positioned between adjacent battery cells 102 to separate the battery cells 102 from one another. As the structural ribs 302 can be rigidly attached to both the base portion 112 and the top portion of the housing, the structural ribs 302 can protect the battery cells 102 not only in the x and y directions, but also in the z direction. It will be understood that, in other embodiments, discrete protection can be provided for the battery cells 102. For example, the ribs 302 would not extend the length of the battery cell 102 as shown in FIG. 9, but are positioned only in discrete strategic places. By providing discrete protection in strategic locations, the amount of material needed for cell protection is minimized, thereby also minimizing the weight and height of the device. In an embodiment, the ribs 302 can be formed of a thermoplastic material, such as polycarbonate-ABS. According to another embodiment, the ribs 302 may be formed of a different material, such as metal.

The height (in the z direction) of the structural ribs 302 is higher than the height (in the z direction) of each battery cell 102 so that the structural ribs can prevent deflection of the base portion 112 as well as the top portion of the housing. That is, the ribs interface with both the base portion 112 and the top portion of the housing to prevent compressive forces from the top and the bottom of the housing. The height of the structural ribs 302 can be higher than the height of the battery cells 102 at their maximum height in their maximum swell condition. The tops of the ribs 302 can interface with certain features of the top portion of the housing such that the ribs 302 are in contact with both the base portion 112 and the top portion of the housing. In some embodiments, the structural ribs 302 can be molded to the base portion 112 of the housing such that it is an integral part of the housing. During assembly, the battery cells 102 can be positioned in their places between the ribs 302. In other embodiments, the ribs 302 can be molded to the front portion of the housing. In still other embodiments, the structural ribs 302 can be a separate component that is rigidly attached to the housing.

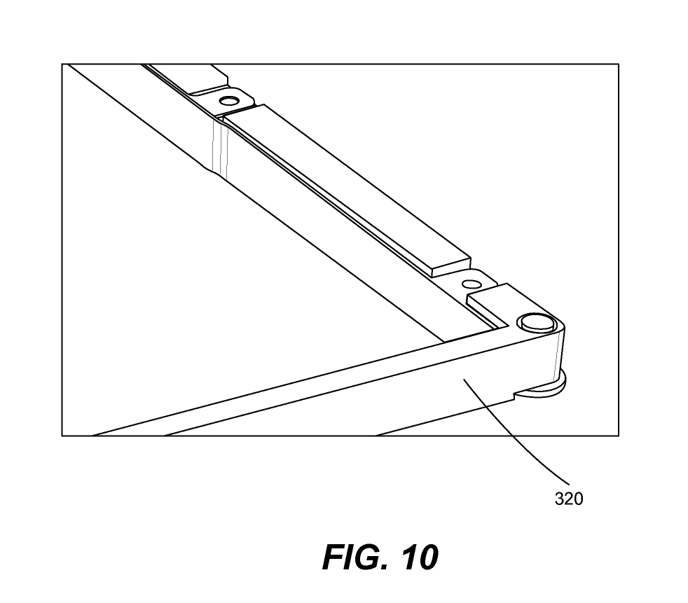

In some embodiments, an integrated interconnect frame 320 can be used, as shown in FIG. 10, for providing both cell mounting tabs and protection to the battery cell 102. Thus, instead of the structural ribs 302 shown in FIG. 3, a frame 320 can be provided to extend around the perimeter of each battery cell 102 to provide protection, as shown in FIG. 10. The frame 320 can also include a circuit adhered thereto. Thus, the frame 320 would provide cell mounting tabs as well as cell protection, and can be used instead of a compression band 104.

The frame 320 can be formed of a plastic material and either integrally molded on the base portion 112 or attached to the based portion 112. Alternatively, the frame 320 can be formed of another suitable material for providing protection to the battery cell 102 and for insulation between the electrode tabs 106.

The height (in the z direction) of frame 320 is higher than the height (in the z direction) of each battery cell 102 (in its maximum swell condition) so that the frame 320, similar to the structural ribs 302, can prevent deflection of the base portion 112 as well as the top portion of the housing. Thus, the frame 320 can prevent compressive forces from the top and the bottom of the housing from damaging the battery cell 102.

In some embodiments, battery cell distribution can be adjusted. For example, the battery cells 102 can have different voltages or different types of cells can be used in the device. For example, in some embodiments, the portable device can include multiple power sources and the power conditioning circuitry can be configured to adjust output voltages based upon the charge states of one or more of the power sources.

The battery cells 102 can be the same or different sizes or even different types of batteries. The battery cells 102 can also be positioned in different locations and separate from one another, but can also be coupled to one another. When coupled together, the battery cells 102 can use power conditioning circuitry, which is capable of adjusting the voltage of each battery cell 102 depending on its current charge level, how it is coupled to other battery cells, charge levels of other battery cells, and the requirements of associated device components. It will be understood that the battery cells 102 may have different sizes and shapes and may be distributed in the housing to take advantage of available space in order to minimize the overall size of the device.

In some embodiments, the housing of the portable device can be formed of aluminum. It will be appreciated that an aluminum housing can act as a heat sink to dissipate heat from the battery cells 102 because the battery cells 102 are in close proximity to the base portion 112 of the housing. According to the described embodiments, as the cells 102 are directly adhered to the base portion 112 and can conform to the shape of the base portion 112, the distance between the battery cell 102 and the base portion 112 of the housing can be as little as the thickness of the adhesive used to adhere the battery cell 102 to the base portion 112. The close proximity of the cells 102 to the base portion 112 allows the base portion 112 to act as a heat sink to help dissipate the heat from the battery cells 102 to prevent overheating and damage of the cells 102 as well as other components of the device.

According to the embodiments described herein, the battery cells 102 are each directly adhered to the housing of the device without a separate battery pack or enclosure. As the battery cells 102 are not enclosed in a separate pack, they are therefore easily accessible. Thus, the lack of a separate pack makes it easier to identify and repair or replace faulty battery cell 102. A removal mechanism 502, such as a pull tab or a removal handle, can be attached to the battery cell 102 to facilitate removal of a battery cell 102 that needs to be repaired or replaced.

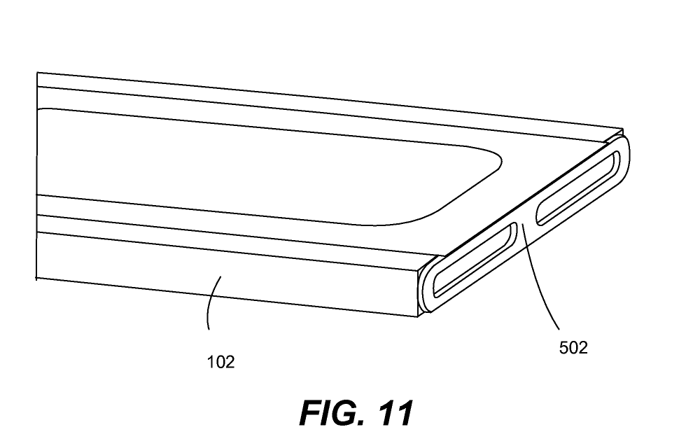

FIG. 11 is a perspective view of the underside of an embodiment of a battery cell 102 with a removal handle 502 adhered to the battery cell 102. The removal handle can be used to aid in the removal of a battery cell 102 if the battery cell 102 needs to be replaced or repaired. As shown in FIGS. 4 and 11, the handle 502 can be positioned at one end of the cell 102 opposite the terrace 402, and the removal handle 502 can extend underneath the battery cell 102. When the handle 502 is pulled vertically upward, its adhesion to the VHB or other adhesive under the cell 102 aids in the removal of the battery cell 102. The removal handle 502 can be formed of a rigid plastic material to provide protection to the battery cell 102 in the z direction. In another embodiment, the removal handle can be formed of a different rigid material, such as metal.

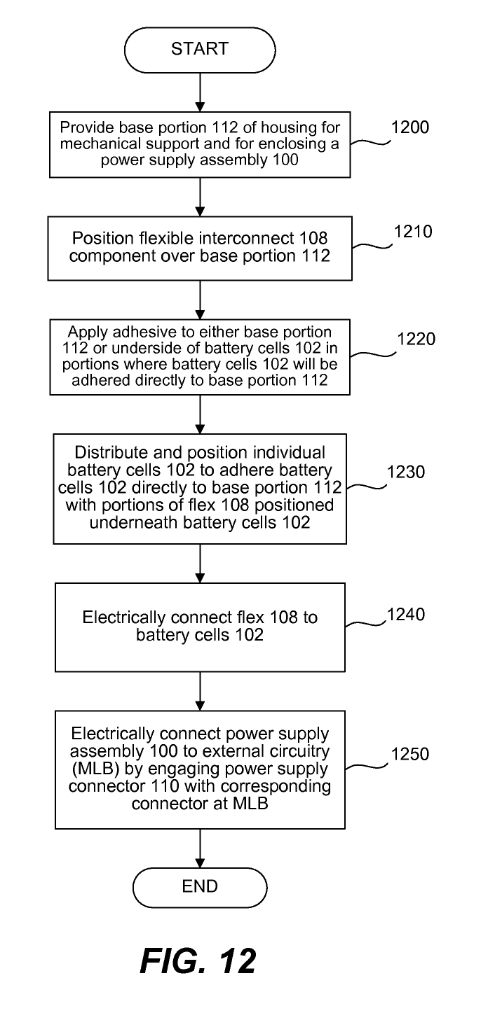

A process for attaching and connecting an embodiment of a power supply assembly in an electronic device will be described with reference to FIG. 12. A process for assembling and connecting the components of the power supply assembly 100 will be described below with reference to steps 1200-1250. In step 1200, a base portion 112 of a housing is provided for mechanical support for the power supply assembly 100 as well as for enclosing the power supply assembly 100 and other operational components of the device. In one embodiment, the base portion 112 is formed of aluminum.

In step 1210, a flexible interconnect 108 component is positioned over the base portion 112 such that the flex 108 is positioned on an inner wall of the base portion 112. In step 1220, adhesive is applied either to the base portion 112 or on the underside of individual battery cells 102 only in portions where the battery cells 102 will be directly adhered to the base portion 112. Individual battery cells 102 are then distributed and positioned over the flex 108 and base portion 112 such that portions of the flex 108 are underneath the battery cells 102 as the battery cells 102 are adhered directly to the base portion 112 in step 1230. It will be understood that adhesive is not applied in portions where the flex 108 will be positioned between the battery cell 102 and the base portion 112 of the housing. As discussed above, different types of cells having different sizes and voltages may be used. The battery cells 102 can also be positioned between structural ribs 302, which provide protection to the battery cells 102.

In step 1240, the flex 108 is electrically connected to the battery cells 102. In an embodiment, the tab portions of the flex 108 can be bent upward to fold over electrode tabs 106 in the terrace regions 402 of the battery cells 102. The flex 108 can be held in place using a fastener, such as a screw. The screw can compress the electrode tabs 106 and flex 108 together, thereby maintaining contact so that the two components can stay electrically connected.

According to this embodiment, in step 1250, the power supply assembly 100, which is electrically connected to the flex 108, is electrically connected to external circuitry, such as a MLB, by engaging the power supply connector 110 with a corresponding connector at the MLB. The power supply connector 110 can be electrically connected to the flex 108 at any time during assembly or can even be pre-assembled with the flex.

The advantages of the invention are numerous. Different aspects, embodiments or implementations may yield one or more of the following advantages. Many features and advantages of the present invention are apparent from the written description and, thus, it is intended by the appended claims to cover all such features and advantages of the invention. Further, since numerous modifications and changes will readily occur to those skilled in the art, the invention should not be limited to the exact construction and operation as illustrated and described. Hence, all suitable modifications and equivalents may be resorted to as falling within the scope of the invention.

What is claimed is:

1. A power supply assembly for a computing device, comprising:
a plurality of battery cells, wherein each battery cell is directly attached to a housing for enclosing operational components of the portable computing device, wherein each battery cell comprises an electrode assembly including an anode, a cathode, and an electrolyte; and
a protective structure adjacent to a battery cell, wherein the protective structure is configured to protect the battery cell from a compressive force applied to the housing of the portable computing device, the protective structure being attached to or integral with the housing and having a height greater than that of each of the battery cells;

2. The power supply assembly of claim 1, wherein the plurality of battery cells comprises battery cells formed of a compliant material.

3. The power supply assembly of claim 1, wherein the plurality of battery cells comprises battery cells of different voltages.

4. The power supply assembly of claim 1, further comprising an interconnect component for electrically interconnecting the battery cells with one another, wherein portions of the interconnect component are positioned between the housing and the battery cells.

5. The power supply assembly of claim 4, wherein the interconnect component is formed of a flexible material.

6. The power supply assembly of claim 4, wherein the interconnect component is electrically connected to a battery cell at one end of the battery cell.

7. The power supply assembly of claim 4, wherein a battery management unit is coupled to or integrated with the interconnect component.

8. The power supply assembly of claim 1, wherein the protective structure is a frame around a perimeter of a battery cell.

9. The power supply assembly of claim 1, wherein the protective structure is positioned in a discrete location adjacent a battery cell.

10. A power source for a portable computing device, comprising:
a plurality of battery cells directly adhered to a housing of the portable computing device, wherein the battery cells have shapes that can conform to a shape of a corresponding portion of the housing;
an interconnect component electrically interconnecting the plurality of battery cells, wherein portions of the interconnect component are positioned between a battery cell and the housing; and
a protective structure in close proximity to the battery cells, wherein the protective structure is configured to protect a battery cell from damage due to a compressive force on the housing.

11. The power source of claim 10, wherein the protective structure is formed integrally with the housing.

12. The power source of claim 10, wherein the protective structure is a frame around a perimeter of a battery cell, the frame being attached to or integral with the housing.

13. The power source of claim 10, wherein the protective structure comprises ribs positioned discretely near the battery cells.

14. The power source of claim 10, wherein the interconnect component is also electrically connected to circuitry of the computing device external to the power source.

15. The power source of claim 10, wherein the interconnect component comprises a flexible material.

16. The power source of claim 10, wherein the protective structure comprises ribs positioned between battery cells, the ribs being formed integrally with the housing.

17. The power source of claim 10, wherein a battery cell comprises a removal handle on one end, the handle extending underneath the battery cell.

18. The power source of claim 10, wherein the plurality of battery cells comprises battery cells of different voltages.

19. The power source of claim 10, wherein the plurality of battery cells comprises battery cells of different sizes.

20. A method of assembling a power supply assembly in a computing device, comprising:
positioning an interconnect component over a base portion of a housing of the computing device;
positioning a plurality of battery cells over the interconnect component and the base portion such that portions of the interconnect component are underneath the battery cells, wherein each of the battery cells comprise an anode, a cathode, and an electrolyte;
adhering the battery cells to the base portion in portions where the interconnect component is not underneath the battery cells.

21. The method of claim 20, further comprising electrically connecting the interconnect component to the battery cells.

22. The method of claim 20, wherein positioning a plurality of battery cells comprises positioning a battery cell in proximity to a protective structure configured to protect the battery cell from a compressive force applied to the housing of the computing device.

23. The method of claim 22, wherein the protective structure comprises a frame around a perimeter of a battery cell.

24. The method of claim 22, wherein the protective structure comprises a plurality of structural ribs extending from an inner wall of the base portion at a substantially perpendicularly, and the battery cell is positioned between structural ribs.

25. The method of claim 20, further comprising electrically connecting the power supply assembly with other circuitry of the computing device.
